(19) United States
(12) Patent Application Publication
(10) Pub. No.: US 2024/0123472 A1
(43) Pub. Date: Apr. 18, 2024

(54) SELF CLEANING ION GENERATOR DEVICE

(71) Applicant: Global Plasma Solutions, Inc., Charlotte, NC (US)

(72) Inventor: Charles Houston WADDELL, Roanoke, VA (US)

(73) Assignee: Global Plasma Solutions, Inc., Charlotte, NC (US)

(21) Appl. No.: 17/827,123

(22) Filed: May 27, 2022

Related U.S. Application Data
(63) Continuation of application No. 16/272,147, filed on Feb. 11, 2019, now Pat. No. 11,344,922.
(60) Provisional application No. 62/629,295, filed on Feb. 12, 2018.

(51) Int. Cl. B08B 1/32; B01D 53/32; B03C 3/74; H01J 37/04; H01T 23/00

(52) U.S. Cl. CPC B08B 1/32; B01D 53/32; B03C 3/743; H01J 37/04; H01T 23/00

(57) ABSTRACT

A self-cleaning ion generator device includes a first portion with a base portion that extends to an outer edge and a first pair and a second pair of opposed sidewalls extending upwardly from the outer edge and intersect at corners, forming a cavity therein. A second portion includes a base portion that extends to an outer edge selectively secured to the first portion forming a housing. At least one ion emitting device extending from the housing, and at least one cleaning apparatus for cleaning the at least one ion emitting device.

### CROSS REFERENCE TO RELATED PATENT APPLICATION

This application is a continuation of U.S. patent application Ser. No. 16/272,147, filed Feb. 11, 2019, entitled “Self Cleaning Ion Generator Device”, which claims priority to and the benefit of U.S. Provisional Patent Application No. 62/629,295, filed on Feb. 12, 2018, and entitled “Self Cleaning Ion Generator Device,” the entire contents of each of which are incorporated by reference herein.

### FIELD OF THE INVENTION

The present invention relates generally to the field of air treatment, and more particularly to the treatment of air using ionization that has a self-cleaning mechanism for cleaning the emission portion of an ionization device without having to remove the device from the conduit or duct that has a thin profile and a protective grate encircling the electrodes and cleaning assembly.

### BACKGROUND OF THE INVENTION

Air and other fluids are commonly treated and delivered for a variety of applications. For example, in heating, ventilation and air-conditioning (HVAC) applications, air may be heated, cooled, humidified, dehumidified, filtered or otherwise treated for delivery into residential, commercial or other spaces.

Needs exist for improved systems and methods of treating and delivering air for these and other applications. It is to the provision of improved systems and methods meeting these needs that the present invention is primarily directed.

### BRIEF SUMMARY OF THE INVENTION

According to an embodiment of the present invention a self-cleaning ion generator device includes a first portion with a base portion that extends to an outer edge and a first pair and a second pair of opposed sidewalls extending upwardly from the outer edge and intersect at corners, forming a cavity therein. A second portion includes a base portion that extends to an outer edge selectively secured to the first portion forming a housing. At least one ion emitting device extending from the housing, and at least one cleaning apparatus for cleaning the at least one ion emitting device.

According to another embodiment of the present invention, a self-cleaning ion generator device includes a grate surrounding the at least one ion emitting device and the at least one cleaning apparatus.

According to yet another embodiment of the present invention, the at least one cleaning apparatus is powered by a motor housed within the cavity.

According to yet another embodiment of the present invention, a self-cleaning ion generator device that includes at least one ion emitting device has a top portion and a bottom portion, wherein the top portion extends above the housing and the bottom portion is disposed within the cavity of the housing.

According to yet another embodiment of the present invention, a self-cleaning ion generator device that includes at least two emission portions spaced apart and extending from the housing.

According to yet another embodiment of the present invention, a self-cleaning ion generator device that includes at least one cleaning head disposed on the at least one cleaning apparatus for cleaning the at least one ion emitting device.

According to yet another embodiment of the present invention, a self-cleaning ion generator device that includes at least one ion emitting device includes an ion emitting device with a plurality of bristles.

### BRIEF DESCRIPTION OF THE DRAWINGS

The present invention is illustrated and described herein with reference to the various drawings, in which like reference numbers denote like method steps and/or system components, respectively, and in which:

FIG. 1 is a perspective view of the self-cleaning ion generator device;

FIG. 2 is an internal view of the self-cleaning ion generator device;

FIG. 3 is a perspective view of the self-cleaning ion generator device;

FIG. 4 is another internal view of the self-cleaning ion generator device;

FIG. 5 is a perspective view of the self-cleaning ion generator device;

FIG. 6 is a perspective view of the self-cleaning ion generator device;

FIG. 7 is an internal view of the self-cleaning ion generator device; and

FIG. 8 is an exploded view of the self-cleaning ion generator device.

### DETAILED DESCRIPTION OF THE INVENTION

The present invention may be understood more readily by reference to the following detailed description of the invention taken in connection with the accompanying drawing figures, which form a part of this disclosure. It is to be understood that this invention is not limited to the specific devices, methods, conditions or parameters described and/or shown herein, and that the terminology used herein is for the purpose of describing particular embodiments by way of example only and is not intended to be limiting of the claimed invention. Any and all patents and other publications identified in this specification are incorporated by reference as though fully set forth herein.

Also, as used in the specification including the appended claims, the singular forms “a,” “an,” and “the” include the plural, and reference to a particular numerical value includes at least that particular value, unless the context clearly dictates otherwise. Ranges may be expressed herein as from “about” or “approximately” one particular value and/or to “about” or “approximately” another particular value. When such a range is expressed, another embodiment includes from the one particular value and/or to the other particular value. Similarly, when values are expressed as approximations, by use of the antecedent “about,” it will be understood that the particular value forms another embodiment.

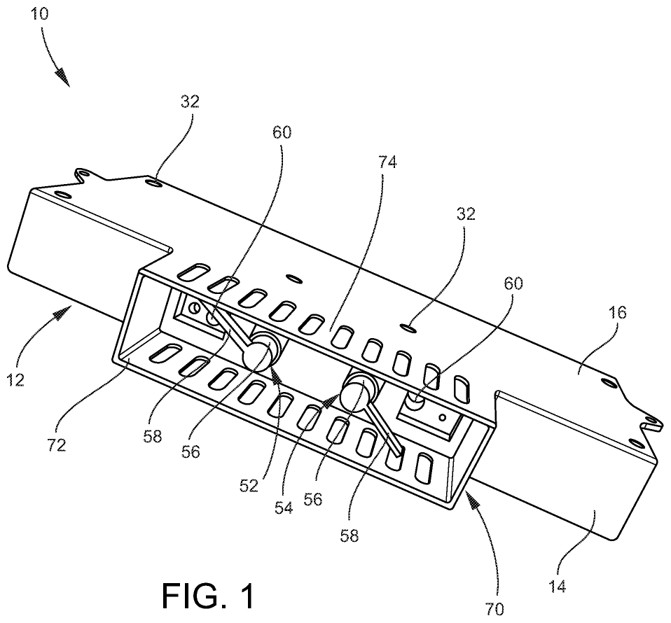

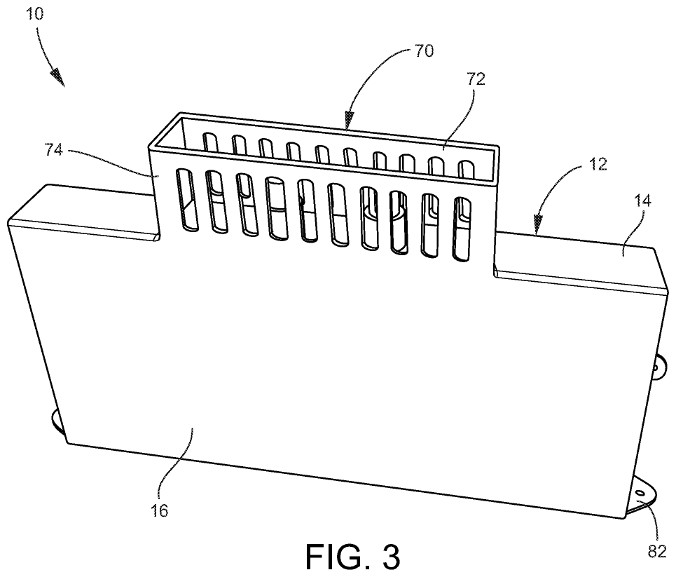

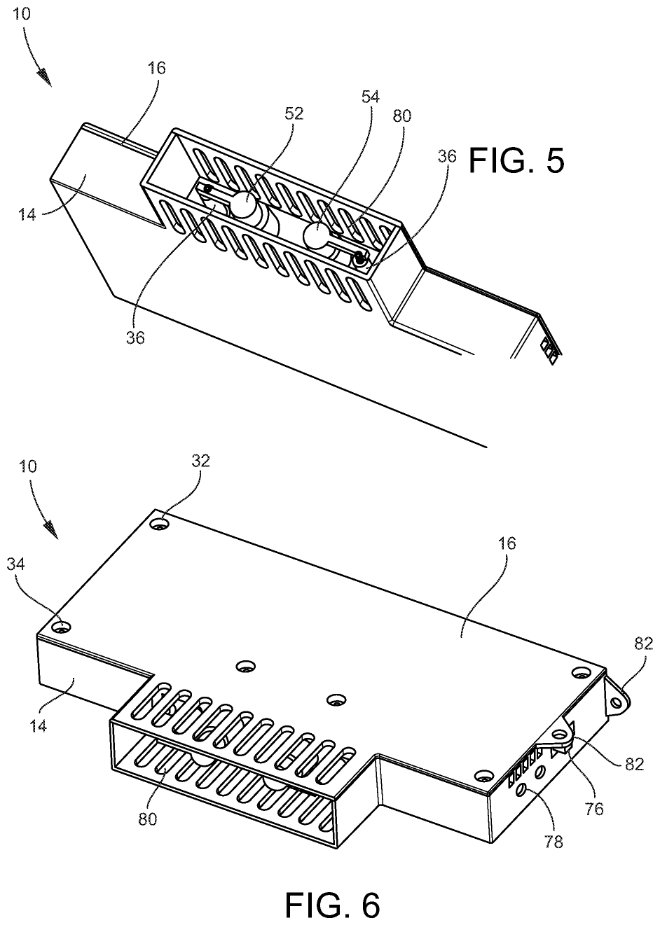

Referring now specifically to the drawings, a self-cleaning ion generator device is illustrated in FIGS. 1, 2, 3, 5, and 6 and is shown generally at reference numeral 10. The device 10 includes a housing 12 having a first portion 14 and a second portion 16. The first portion 14 may be rectangular and is selectively secured to the second portion 16, which may also be rectangular. The first portion 14 contains a base portion 18 that extends to an outer edge and a first pair of opposed sidewalls 20 and a second pair of opposed sidewalls 22 extend upward from the outer edge. The first pair of opposed sidewalls 20 and the second pair of opposed sidewalls 22 intersect at corners forming a cavity 24 therein.

The second portion 16 has a base portion 26 that extends to an outer edge. A lip 28 extends upwardly from the base portion 26 and extends around the periphery of the base portion 26. The lip 28 is off-set a predetermined distance from the outer edge of the base portion 26. In other words, the lip 28 extends upwardly from the base portion 26 and is not engaged to the outer edge of the base portion 26, but is disposed a distance from the outer edge on the base portion 26.

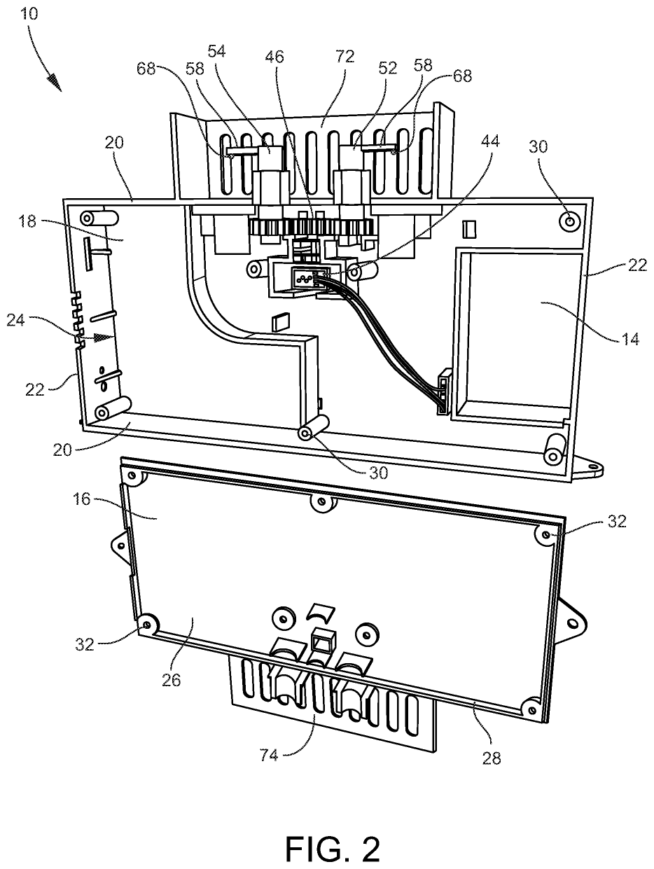

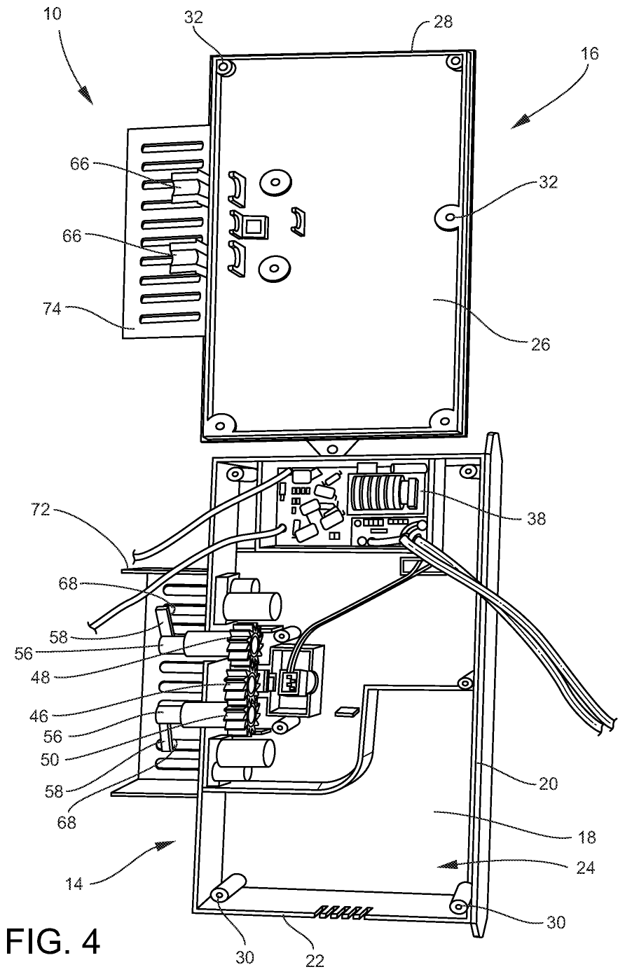

At least one cylindrical bore 30 is engaged to the base portion 18 of the first portion 14 and extends upwardly from the base portion 18. As illustrated in FIGS. 2 and 4, a cylindrical bore 30 is disposed adjacent each corner and extending upwardly from the base portion 18 of the first portion 14. Additional cylindrical bores 16 may be disposed near the central portion of the base portion 18 and extending upwardly therefrom. The cylindrical bores 30 extend to a predetermined height, and as illustrated, extend to the height substantially similar to the height of the first pair of opposed sidewalls 20 and the second pair of opposed sidewalls 22.

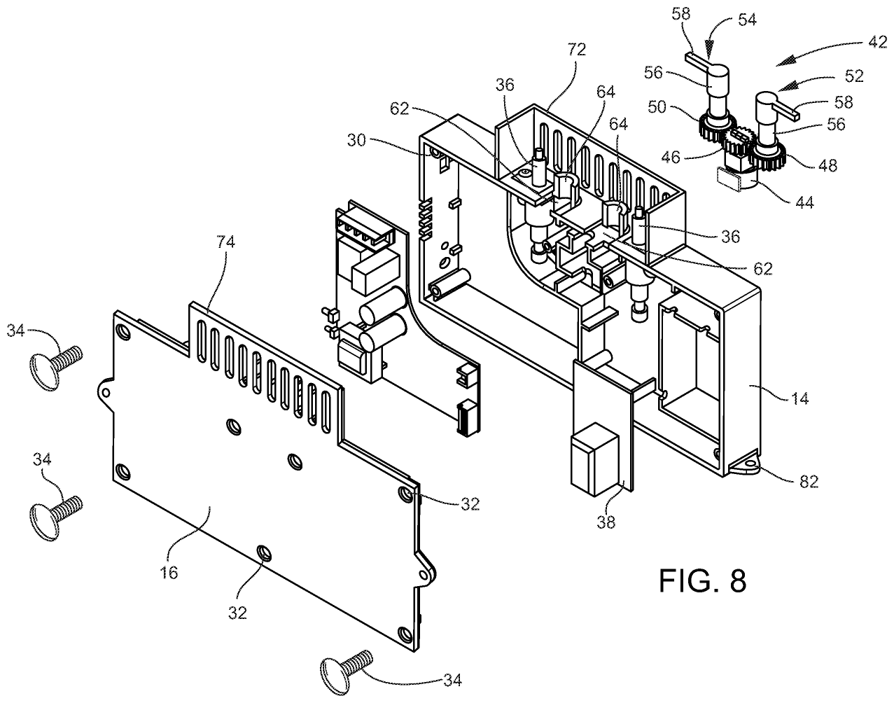

A corresponding hole 32 is positioned on the second portion 16 that extends from the top side to the bottom side of the base portion 26. When the second portion 16 is placed over top the first portion 14, the hole 32 is above the cylindrical bore 30 for inserting a fastening device 34, such as a screw, bolt, etc. for selectively securing the first portion 14 to the second portion 16, as illustrated in FIG. 8.

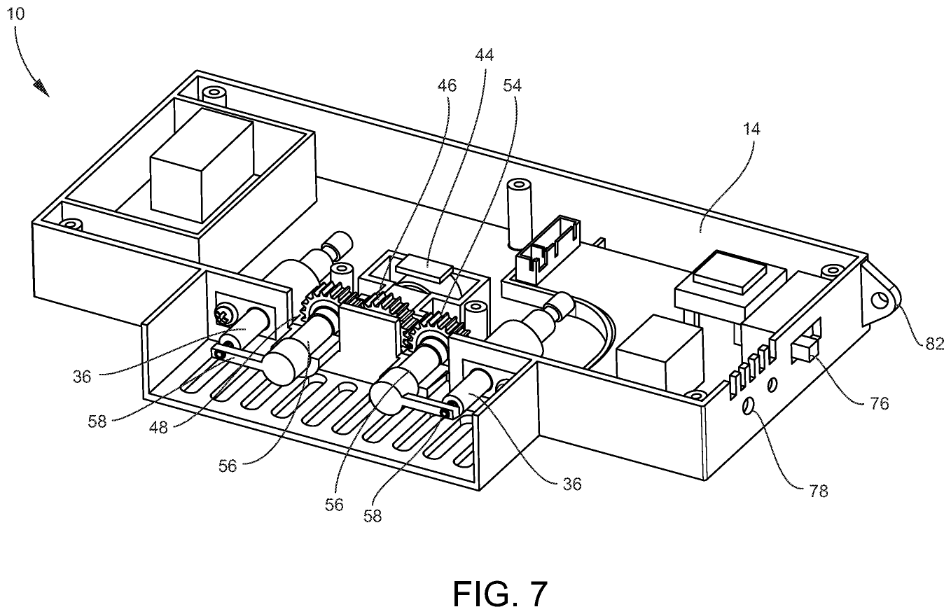

At least one ion emitter device 36, as shown in FIGS. 2, 4, 7, and 8, is positioned within the cavity 25 and is electrically and communicatively coupled to a circuit board 38. As illustrated, the device 10 contains two spaced-apart ion emitter devices 36. The circuit board 38 is contained within the cavity 24 and engaged to the first portion 14. The circuit board 38 may include a power supply source for providing power to the device 10. The power supply provides the electricity to power the ion emitter device 36, and thus, produces ions. The ion emitter device 36 contains an emission portion that is any element capable of emitting ions, such as needles or brushes. As illustrated in the figures, the ion emitter device 36 contains a top portion and a bottom portion. The top portion of the ion emitter device 36 extends outward from the device 10, and specifically outwardly from a sidewall of the first portion 14 and second portion 16 when the first portion 14 and the second portion 16 are in the combined configuration. The top portion contains the emission portion for emitting ions. The bottom portion of the ion emitter device 36 is disposed within the cavity 24 and electrically coupled to the circuit board 38 that is electrically coupled to the power supply. Alternatively, the bottom portion of the ion emitter device 36 may be electrically coupled directly to the power supply.

The emission portion of the ion emitter device 36 may be a needle or a brush. The needle contains an elongate portion that narrows to a point at one end. In other words, the needle has a bottom portion and a top portion. The bottom portion has a width larger than the top portion, wherein the top portion defines a point for allowing ions to emit therefrom. Alternatively, the emission portion may contain a brush that has a plurality of bristles that extend outwardly away from the brush. The brush and its bristles may be made of any material that conducts electricity and the combination of the brush with its bristles and the high voltage wire or electrode may be collectively referred to herein as an electrode. In one embodiment, the bristles of the brush are composed of a thermoplastic polymer imbedded with conductive material that allows the polymer to conduct electricity. For example, the bristles of the brush may be composed of polypropylene or polyethylene and impregnated with carbon. Generally, the bristles of the brush may contain between about 20 to about 80 wt % polypropylene copolymer or polyethylene copolymer, between about 5 to about 40 wt % talc, and from about 5 to 40 wt % carbon black. However, any other resistive, inductive, reactive or conductive plastic or non-metallic material may be utilized for the bristles of the brush. The brushes are replaceable and allowed to be easily disengaged and new bristles may be inserted and retained.

A cleaning assembly 42 is positioned within the device 10. As shown in FIG. 8, the cleaning assembly 42 includes a motor 44, a drive gear 46, a first slave gear 48, a second slave gear 50, a first cleaning apparatus 52, and a second cleaning apparatus 54. The motor 44 is preferably a DC stepper motor that rotates the drive gear 46. The drive gear 46 is engaged to a first slave gear 48 and a second slave gear 54. The teeth of the drive gear 46 interconnection with the teeth of the first slave gear 48 and the second slave gear 54. As the drive gear 46 rotates, it rotates the first slave gear 48 and the second slave gear 50. The first slave gear 48 and the second slave gear 50 are disposed on opposite sides of the drive gear 46. The first cleaning apparatus is engaged to the first slave gear 48. The second cleaning apparatus 54 is engaged to the second slave gear 50.

The first cleaning apparatus 52 contains an elongate portion 56 that extends outwardly from the first slave gear 48. The second cleaning apparatus 54 contains an elongate portion 56 that extends outwardly from the second slave gear 50. A cleaning portion 58 is disposed on the first and second cleaning apparatuses (52, 54). The cleaning portion 58 extends outward from the elongate portion 56 such that it can contact the top portion of the respective ion emitter devices 36.

An upper sidewall of the first portion 14 and the second portion 16 may contain at least one bore 60, and as illustrated in FIG. 1, the upper end may contain at least two bores 60. The upper sidewall is one sidewall of the first pair of opposed sidewalls 20 or the second pair of opposed sidewalls 22. The bores 60 extend from the inner side to the exterior side of the upper sidewall. The ion emitting devices 36 extend through the bores 60 with the top portion extending above the bore 60 and the bottom portion extending below the bore 60.

As illustrated in FIG. 4, a first high voltage wire engages one of the ion emitting devices 36 and a second high voltage wire engages the other ion emitting device 36 for providing electricity to produce the ions from the top portion of the ion emitter device 36.

Two spaced-apart openings 62 are disposed within the upper sidewall of the first portion 14. As shown in FIGS. 2, 4, 7, and 8, the openings contain a u-shaped portion formed within the upper sidewall that is open on one side. When the second portion 16 is engaged to the first portion 14, the base portion 26 serves to enclose the open side. As shown in FIGS. 2 and 8, a first arcuate portion 64 extends upwardly above the openings 62 on the first portion 14. The first arcuate portions 64 are adjacent the bottom portion of the u-shaped opening 62 and extend upwardly from the opening 62. A pair of second arcuate portions 66 are disposed on the second portion 16. As illustrated in FIG. 2, the second arcuate portions 66 are disposed adjacent the upper edge of the second portion 16. When the first portion 14 and second portion 16 are selectively secured, the first arcuate portions 64 and the second arcuate portions 66 form a circular collar that extends upwardly from the openings 62. When selectively secured, the circular collar is hollow and completely encircles the opening 62 and extends perpendicularly upward from the upper sidewall. As shown in FIG. 2, the circular collar formed by the engagement of the first arcuate portion 64 and the second arcuate portion 66 encircles the elongate portion 56 of the cleaning assembly 42. As shown in FIG. 2, the motor 44, drive gear 46, first slave gear 48, and second slave gear 50 are positioned within the cavity 24 of the device 10. The first portion of the elongate portion 56 is also positioned within the cavity 24, but extends through the opening 62 and above the upper edge of the circular collar formed by the engagement of the first arcuate portion 64 and the second arcuate portion 66.

A cleaning head 68 is disposed on the cleaning portion 58 for contacting and cleaning the emission portion of the ion emitter device 36. Preferably, the cleaning head 68 is removable and replaceable. The cleaning head 68 may contain any device that may clean the emission portion of the ion emitter device 36, such as a brush, cloth, foam pad, etc.

The circuitry of the circuit board 38 may also include a timing circuit for timing the motor 44 for engagement or activation at a predetermined time. The drive gear 46 is powered by the motor 44 and is operationally connected to a timing circuit that activates the motor 44 at a predetermined interval. By way of example only, the drive gear 46 may be activated between every 12 to 24 hours, thus rotating the first slave gear 48 and the second slave gear 50 that rotates the first cleaning apparatus 52 and the second cleaning apparatus 54 for cleaning the emission portion of the ion emitter devices 36. While the cleaning apparatuses (52,54) are activated, the device 10 ceases to produce ions, thus preventing any loose particles from sticking to the cleaning heads 68.

A grate 70 is disposed on one side of the device 10. The grate 70 has a first side 72 and a second side 74. The first side 72 of the grate 70 is disposed on the exterior side of the upper sidewall. The first side 72 has a first end portion and a second end portion that are spaced-apart from each other and extend along the face of the exterior side of a sidewall. A first face portion of the grate 70 extends along the length of a sidewall and the first side of the face portion engages an end of the first end portion. The second side of the first face portion engages an end of the second end portion. Preferably, the first and second end portions are solid, and the first face portion has a plurality of longitudinally extending slots 80 extending from the interior side to the exterior side of the first face portion, allowing air to flow through the first face portion.

A second face portion extends from the upper edge of a side of the base portion 26 of the second portion 16. The second face portion is configured identically to the first face portion with a plurality of longitudinally extending slots 80 extending from the interior side to the exterior side of the second face portion, allowing air to flow through the second face portion. When the first portion 14 and second portion 16 are engaged to each other, a first end of the second face portion is engaged to an end of the first end portion and the second end of the second face portion is engaged to an end of the second end portion. When the first side 72 and the second side 74 of the grate 70 are engaged to each other, the grate 70 is rectangular shaped and encloses the ion emitter devices 36 and the first cleaning apparatus 52 and the second cleaning apparatus 54. The top side of the grate 70 is open. The grate 70 is wide enough to allow the cleaning portion 58 to make a complete rotation around the elongate portion 56.

In an alternative embodiment of the present invention, the device 10 includes an alarm feature, including alarm contacts, that are communicatively coupled to a building management system that sends a signal to the building management system if ions are not produced by the device 10. The building management system then sends an alert informing a user that the device 10 is not producing ions. A test button 76 may also be located on the device 10 to check the motor status during preventive maintenance and a light 78, such as a light-emitting diode (LED) light, may be illuminated, indicating a cleaning test is being conducted. A light, such as an LED light, is illuminated and indicating power is being supplied to the device 10,

The device 10 may produce approximately equal amounts of positive and negative ions, regardless of airflow velocity or other conditions such as humidity or temperature. In example forms, the device 10 produces positive ions and negative ions in a concentration of at least about 200 million ion/cc, and operates on 24 VAC, 110 VAC or 200 VAC to 240 VAC without the use of an external transformer. In alternate embodiments, the device generates negative ions only, or positive ions only, or generate negative ions and positive ions in unequal quantities. The device 10 optionally utilizes nano-electronic components allowing the device to be very compact, requiring less than 10 watts/ion generator module. The bottom portion 12 may contain terminals extending therefrom for connecting the 24 VAC, 110-240 VAC, and neutral input.

The device 10 may be positioned and secured in place within a conduit or the housing of the air handler unit, such as a duct, such that the emission portion is aligned generally perpendicularly to the direction of the airflow across the device 10, to prevent recombination of the positively charged ions with the negatively charged ions. The device 10 may include attachment devices 82 with a centrally located bore for receiving an attachment device, allowing the device to be secured in place. The device 10 may be mounted in a conduit within a variable refrigerant flow HVAC system, including ducted and ductless units.

The treatment of air by delivery of bipolar ionization to an airflow within a conduit according to the systems and methods of the present invention may be utilized for various purposes. For example, application of bipolar ionization to an airflow within an HVAC conduit such as an air handler housing or duct may be utilized to abate allergens, pathogens, odors, gases, volatile organic compounds, bacteria, virus, mold, dander, fungus, dust mites, animal and smoke odors, and/or static electricity in a treated air space to which the airflow is directed. Ionization of air in living and working spaces may reduce building related illness and improve indoor air quality; and additionally, can reduce the quantity of outside air needed to be mixed with the treated indoor air, reducing heating and cooling costs by enabling a greater degree of air recirculation.

During use, once power is provided to the device 10, the device 10 initiates an internal check on all systems. After initializing and the check has confirmed all systems are operational, an LED light 78 will blink “on” proving the device has been powered. The device 10 also contains a test button 76 that when pushed, initiates a cleaning cycle of the device 10, causing the motor 44 to engage, thus rotating the drive gear 46, and causing the first and second cleaning apparatuses (52,54) to rotate and clean the emission portion of the ion emitter devices 36.

Although the present invention has been illustrated and described herein with reference to preferred embodiments and specific examples thereof, it will be readily apparent to those of ordinary skill in the art that other embodiments and examples may perform similar functions and/or achieve like results. All such equivalent embodiments and examples are within the spirit and scope of the present invention and are intended to be covered by the following claims.

What is claimed is:

1. A self-cleaning ion generator device, comprising:
a housing defining a cavity therein;
at least one ion emitting device extending from the housing; and
at least one cleaning apparatus configured to rotate to clean the at least one ion emitting device.

2. The self-cleaning ion generator device of claim 1, further comprising a grate surrounding the at least one ion emitting device and the at least one cleaning apparatus.

3. The self-cleaning ion generator device of claim 1, wherein the cleaning apparatus is powered by a motor housed within the cavity.

4. The self-cleaning ion generator device of claim 1, wherein the at least one ion emitting device has a top portion and a bottom portion, wherein the top portion extends above the housing and the bottom portion is disposed within the cavity of the housing.

5. The self-cleaning ion generator device of claim 1, further comprising at least two ion emitting devices spaced apart and extending from the housing.

6. The self-cleaning ion generator device of claim 1, further comprising at least one cleaning head disposed on the at least one cleaning apparatus for cleaning the at least one ion emitting device.

7. The self-cleaning ion generator device of claim 1, wherein the at least one ion emitting device consists of a plurality of bristles extending therefrom.

8. The self-cleaning ion generator device of claim 1, wherein the device is mounted by attachment devices disposed on the housing.
